(19) United States
(12) Patent Application Publication
(10) Pub. No.: US 2026/0082911 A1
(43) Pub. Date: Mar. 19, 2026

(54) FLUID-PERMEABLE COOLER FOR COOLING A POWER MODULE

(71) Applicant: Robert Bosch GmbH, Stuttgart (DE)

(72) Inventors: Maik Paehrisch, Reutlingen (DE); Marlies Breitenbach, Reutlingen (DE); Max Florian Beck, Vaihingen An Der Enz (DE); Tobias Hoppe, Kuppenheim (DE)

(21) Appl. No.: 19/108,266

(22) PCT Filed: Aug. 30, 2023
(86) PCT No.: PCT/EP2023/073754

§ 371 Date: Mar. 3, 2025

(30) Foreign Application Priority Data
Sep. 15, 2022 (DE) 10 2022 209 698.3

(51) Int. Cl. H01L 23/46; H01L 21/48

(52) U.S. Cl. CPC H10W 40/40; H10W 40/037

(57) ABSTRACT

The present invention relates to a fluid-permeable cooler (100) for cooling a power module (208) that comprises a power substrate. The fluid-permeable cooler (101) comprises a first metal part (101), a second metal part (102) and a cooling structure (1). The first metal part (101) and the second metal part (102) are interconnected by means of a soldering process and define a cooling channel (111) which is permeable by a fluid and in which the cooling structure (1) is located.

The first metal part (101) comprises a receiving region (109) to which the power module (208) can be attached. The first metal part (101) is made from a metal material which has an expansion coefficient that is greater than the expansion coefficient of the power substrate (208). The invention also relates to a power electronics assembly (1000) having a cooler (100) of this kind and a power module (200).

### BACKGROUND

The present invention relates to a fluid-permeable cooler for cooling a power module having a power substrate. The invention also relates to a power electronics assembly having a power module comprising a power substrate and a fluid-permeable cooler of this kind. The power electronics assembly may in particular comprise a plurality of power modules that are cooled by means of the cooler.

Power semiconductors of a power module in power electronics carry high electric currents. Together with switching losses, the resulting conduction losses are the cause of high heat dissipation, which must be dissipated over a very small area. The maximum permissible semiconductor temperature is critical to failure, which is why minimizing the thermal resistance between the semiconductor and the coolant is of central importance. For efficient cooling, the power substrates are applied to a fluid-permeable cooler.

### SUMMARY

The fluid-permeable cooler according to the present invention for cooling a power module comprising a power substrate has the advantages of a flexible design of the cooler and a good cooling performance. This is achieved by a fluid-permeable-cooler for cooling a power module having a power substrate comprising a first metal part, a second metal part and a cooling structure. The first metal part and the second metal part are interconnected by means of a soldering process. In other words, the first metal part and the second metal part are soldered together. The first metal part and the second metal part define a cooling channel through which a fluid can flow and in which the cooling structure is located. The first metal part comprises a receiving region to/on which the power module can be attached. The first metal part is made from a metal material which has an expansion coefficient that is greater than the expansion coefficient of the power substrate, so that heat-induced expansion of the first metal part is reduced. Prior to the soldering process, the first metal part may advantageously be a metal part pre-plated with a soldering layer, in particular a roll-plated metal part. Accordingly, the second metal part may advantageously be a metal part pre-plated with a soldering layer, in particular a roll-plated metal part, prior to the soldering process. It is also possible that alternatively or additionally to the pre-plated configuration of the first metal part and/or the second metal part, the connection between the first metal part and the second metal part is carried out by means of at least one hard solder film or hard solder paste. In particular, the expansion coefficient mentioned above may be a linear expansion coefficient. The power substrate preferably comprises a carrier plate and at least one conductor track. For example, the expansion coefficient of the first metal part may be at least twice, in particular at least three times, as high as the expansion coefficient of the power substrate.

The power substrate and the first metal part preferably have different yield strengths. The yield strength is a material characteristic and describes the mechanical stress up to which a material is elastically deformable.

The metal material may preferably be a pure metal or a metal alloy.

Preferably, the metal material of the first metal part after the soldering process has a yield strength that is greater than 30 N/mm². In other words, the metal material of the first metal part preferably has a yield strength greater than 30 N/mm² in its soldered state. This means that the metal material of the first metal part has the mentioned yield strength after its thermal treatment caused by the soldering process. This ensures that when the first metal part is bent due to the different expansion coefficients of the first metal part and the power substrate, the first metal part only deforms in the elastic range below the yield strength. At an initial temperature, the first metal part returns to its original state. This can prevent plastic deformation, in particular bending, of the first metal part, in particular in the area of the power substrate, which could otherwise occur during heating/cooling due to the greater expansion/shrinkage of the first metal part than the power substrate and which would continuously increase under cyclic loads.

In particular, the metal material may have an upper yield strength and a lower yield strength, wherein in this case the yield strength, which is greater than 30 N/mm², corresponds to the upper yield strength.

Advantageously, plastic deformation of the first metal part, whose metal material has a yield strength greater than 30 N/mm², can be avoided at a heat flux density of less than 600,000 W/m² and/or a temperature difference between an initial temperature and a final temperature which is at least 120° C.

The metal material of the first metal part has a thermal conductivity coefficient greater than 190 W/(m*K), preferably greater than 200 W/(m*K). This means that heat generated by the power module may be efficiently transferred from the first metal part to the fluid flowing through the cooling channel.

The first metal part and the second metal part are preferably interconnected by means of a hard soldering process. This means that there is preferably a bonding hard soldering layer between the first metal part and the second metal part. This means that the first metal part and the second metal part can preferably be hard soldered.

Advantageously, the cooling structure may contact the first metal part and/or the second metal part. In particular, the cooling structure may be connected to the first metal part and/or the second metal part in an advantageous manner by means of a hard soldering process. The bonding hard soldering layer interconnecting the first metal part and the second metal part may preferably also connect the cooling structure to the first metal part and/or the second metal part.

According to an advantageous embodiment of the invention, the metal material of the first metal part comprises magnesium (i.e. the metal material is a metal alloy), wherein the second metal part is made from a metal material which does not comprise magnesium. Here, the second metal part may be a pure metal part or a metal alloy. In this embodiment of the invention, the mass percentage of magnesium in the mass of the first metal part is less than 1%.

According to an alternative embodiment of the invention, the metal material of the first metal part comprises magnesium, wherein the second metal part is formed from a metal material comprising magnesium. That is to say that both the metal material of the first metal part and the metal material of the second metal part are metal alloys and each comprises magnesium. Advantageously, a mass percentage of magnesium from the mass of the first metal part and from the mass of the second metal part is less than 1% in total. Particularly preferably, the mass percentage of magnesium of each metal part of the first metal part and the second metal part may be less than 0.5% of the mass of the corresponding metal part.

Due the mass percentages specified, the first metal part/two metal parts may be easily interconnected by means of a hard soldering process if the first metal part/two metal parts comprise magnesium.

Preferably, the metal material of the first metal part is an aluminum alloy, wherein the metal material of the first metal part has the material state O after the soldering process. In other words, the metal material of the first metal part in the soldered state of the first metal part has the material state O. The material state O in which the properties required for the soft annealed state are achieved by hot forming processes.

The cooling structure in the context of the present invention is preferably understood as a surface-enhancing, flow-conducting and heat-transfer-increasing structure.

The cooling structure may preferably comprise a cooling fin structure and/or a pin structure (cooling pin structure). It is also conceivable that the cooling structure alternatively or additionally also comprises a cooling structure element or a plurality of cooling structure elements that have a different shape than a cooling fin or pin. It is in particular possible for the cooling structure to have a plurality of cooling structure elements of different shapes. For example, the cooling structure may comprise a cooling fin and a pin, or a plurality of cooling fins, and a plurality of pins. In the context of the present invention, a cooling fin and a pin may each be referred to as a cooling structure element.

The cooling fin structure may preferably comprise (only) a cooling fin or a plurality of cooling fins, which are preferably located one behind the other in a flow direction. The flow direction corresponds in particular to a main flow direction of a fluid used as a coolant, which flows through openings formed by the cooling fin(s). In particular, the main flow direction is in this case the direction in which the fluid mainly flows, i.e., the direction in which a velocity component of the fluid is greater than a velocity component of the fluid in a direction perpendicular to the main flow direction. The main flow direction preferably corresponds to a direction in which the fluid enters the fluid-permeable cooler.

The cooling fin structure may in particular also be referred to as a turbulator. The cooling fin is formed by a wave profile periodically repeating in a repeating direction.

The cooling structure is preferably made, at least partially, particularly completely, of a material and/or coated with a material that features a thermal conductivity coefficient greater than 200 W/(m-K). Advantageously, the cooling structure may be at least partially, in particular completely, made of aluminum or coated with aluminum.

In particular, these configurations relate to the cooling structure elements of the cooling structure.

In the context of the present invention, the fluid flowing through the cooler may in particular also be referred to as cooling fluid.

The invention also relates to a power electronics assembly having a power module with a power substrate and comprising a fluid-permeable cooler previously described. The power module is attached to/on the receiving region of the first metal part of the fluid-permeable cooler by means of the power substrate.

The power substrate may preferably be made from copper and/or ceramic (AMB/DBC power substrate; AMB: active metal braze; DBG: direct copper bonding).

For the purpose of a low thermal resistance between the power substrate and the cooler, in particular the first metal part, the power substrate can preferably be joined to the cooler, in particular the first metal part, by means of a soft soldering process, optionally also a sintering process. This means that the power module is preferably joined to the fluid-permeable the cooler or the first metal part by means of a layer generated by a soft soldering process or a sintering process, which is thus a soft soldering layer or a sintering layer.

The power module preferably comprises one or more power semiconductors. A power semiconductor generates heat during operation of the power module, which may be dissipated by the cooler.

### BRIEF DESCRIPTION OF THE DRAWINGS

In the following, embodiment examples of the invention are described in detail with reference to the accompanying drawing. The drawings show:

FIG. 1 is a schematic simplified sectional view of a power assembly according to the invention having a fluid-permeable cooler according to an exemplary embodiment of the invention.

### DETAILED DESCRIPTION

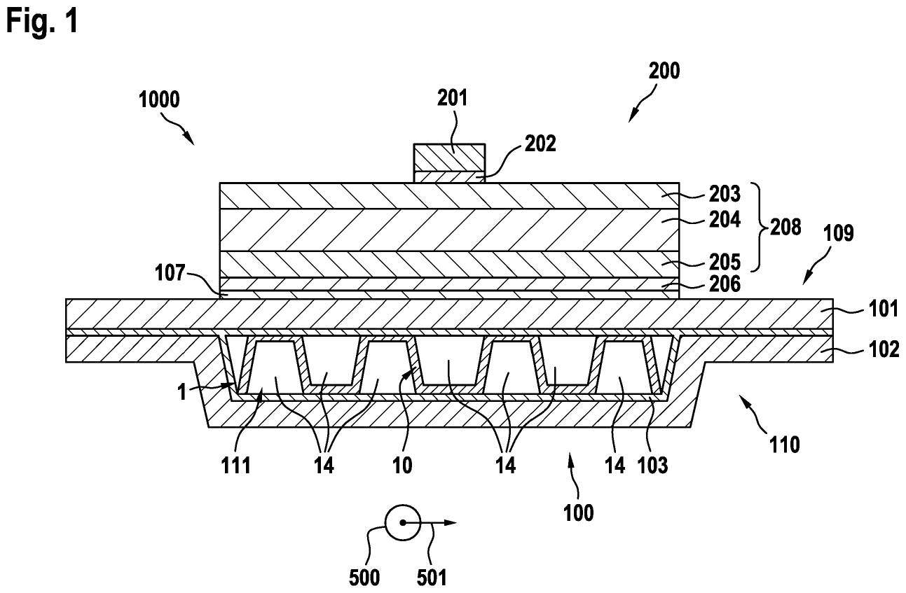

Referring to FIG. 1, a power electronics assembly 1000 according to the invention having a power module (power electronics structural unit) 200 and a fluid-permeable cooler 100 according to an exemplary embodiment of the invention is described below. It is also possible for the power electronics assembly 1000 to include a plurality of power modules 200.

As can be seen from FIG. 1, the power module 200 comprises a support plate 204, conductor tracks 203, 205, and power semiconductor 201. The conductor tracks 203, 205 are designed in particular as copper conductor tracks, whereby the carrier plate 204 is preferably made of ceramic.

The power semiconductors 201 are applied to the conductor track 203 by a layer 202. In particular, the layer 202 is in this case designed as a solder or sintered layer.

The conductor tracks 203, 205 together with the carrier plate 204 form a power substrate 208. The power substrate 208 and thus the power module 200 is joined to the fluid-permeable cooler 100, in particular to the receiving region 109 of the first metal part 101 of the cooler 100, by means of a layer 206 produced by a soft soldering process or a sintering process, which is thus correspondingly a soft soldering layer or sintering layer.

The fluid-permeable cooler 100 further comprises a second metal portion 102 connected to the first metal portion 101 by a soldering process. In other words, the first metal part 101 and the second metal part 102 are soldered together. In particular, the soldering process is a hard soldering process, such that the first metal part 101 and the second metal part 102 are connected by means a bonding hard solder layer 103. In particular, both metal parts 101, 102 are configured as metal sheets.

FIG. 1 also shows that the first metal part 101 is an upper part and the second metal part 102 is a lower part of the housing 110. The first metal part 101 faces the power module 200, whereby the second metal part 102 faces away from the power module 200. Furthermore, the first metal part 101 is plate-shaped in this exemplary embodiment, wherein the second metal part 102 comprises a plate-shaped area and a trapezoidal area in cross-section. However, it is also possible for the first metal part 101 and the second metal part 102 to comprise other shapes. The second metal part 102 may advantageously be produced by means of a deep-drawing process.

A mediation layer 107 is advantageously located between the layer 206 and the cooler 100 (in particular between the layer 206 and the first metal part 101), which is firmly connected to the first metal part 101 and enables wetting of the layer 206. The mediation layer 107 is an optional feature of the power electronics assembly 1000 and can in particular be considered either as a separate part or as part of the cooler 100.

The first metal part 101 and the second metal part 102, which form a housing 110 of the cooler 100 when joined together, define an interior space which serves as the cooling channel 111 of the cooler 100. In other words, the interconnected metal parts 101, 102 define the cooling channel 111 of the cooler 100. The cooling channel 111 is advantageously closed, wherein an inlet and outlet for the fluid is located on the housing of the cooler 100.

A cooling structure 1 is located in the cooling channel 111, which serves as a surface-enlarging, flow-guiding and heat-transfer-enhancing structure for a fluid used as a coolant. The cooling structure 1 is connected to the first metal part 101 and the second metal part 102 by means of the bonding hard soldering layer 103.

In particular, the cooling structure 1 comprises or is a cooling fin structure. To this end, the cooling fin structure has a cooling fin 10 extending in the longitudinal direction of the cooling channel 111 or in a flow direction 500 of the fluid. In this case, the cooling structure 1 thus corresponds to the cooling fin 10. The flow direction 500 corresponds in particular to a main flow direction of a fluid used as a coolant.

As can be seen from FIG. 1, the cooling fin 10 is formed from a wave profile that periodically repeats in a direction of repetition 501. Through-holes 14 are formed through the cooling fin 10, through which the fluid can pass. The cooling fin 10 is preferably made of a material and/or coated with a material that features a thermal conductivity coefficient greater than 200 W/(m K). Advantageously, the cooling fin 10 may be made of aluminum or coated with aluminum. It is also possible that other thermally conductive materials are used for the cooling fin 10 and/or their layer.

In this embodiment, although the cooling fin structure only has one cooling fin 10, it is also possible for the cooling fin structure to have a plurality of cooling fins 10, which are arranged one behind the other in particular in the flow direction 500 of the fluid.

The first metal part 101 is made from a metal material which has an expansion coefficient that is greater than the expansion coefficient of the power substrate 200, so that heat-induced expansion of the first metal part 101 is reduced. The metal material of the first metal part 101 is a metal alloy, preferably an aluminum alloy. However, it is also possible that a pure metal is used as the metal material of the first metal part 101.

By attaching the power substrate 208 to/on the receiving region 109 of the first metal part 101, thermal expansion/shrinkage inhibits the expansion/shrinkage of the first metal part 101 due to the different thermal expansion coefficients of these components, thereby causing the first metal part 101 and thus the cooler 100 to bend.

In particular, to prevent plastic deformation by bending, a higher-strength metal alloy, preferably a higher-strength aluminum alloy, is employed for the metal material of the first metal part 101, such that the first metal part 101 deforms only in the elastic region below the yield strength of the metal alloy during heat-induced bending. When the first metal portion 101 no longer experiences expansion/shrinkage, i.e. at the initial temperature, the first metal portion 101 returns to its original state. The yield strength of the metal alloy for the metal material of the first metal part 101 is greater than 30N /m². It should be noted that the yield strength of the metal alloy is the yield strength that the metal alloy has after the soldering process, i.e. after the heat treatment of the first metal part 101 that has taken place as a result of the soldering process. Advantageously, due to the yield strength of the metal alloy, the first metal part 101 is configured to deform only in the elastic region at a heat flux density of less than 600,000 W/m² and/or a temperature difference between an initial temperature and a final temperature which is at least 120° C.

If the metal alloy of the first metal part 101 is an aluminum alloy, it advantageously has the material state O after the soldering process. In other words, in the soldered state of the first metal part 101, the aluminum alloy of the first metal part 101 advantageously has a material state O.

The power substrate 208 and the first metal part 101 preferably have different yield strengths.

The metal alloy of the first metal part 101 has a thermal conductivity coefficient greater than 190 W/(m*K), preferably greater than 200 W/(m*K). This means that heat generated by the power module 200 may be efficiently transferred from the first metal part 101 to the fluid flowing through the cooling channel 111 and discharged from it so that the power module 200 is cooled.

The second metal part 102 is also advantageously formed from an aluminum alloy. Here, both metal parts 101, 102 may comprise magnesium. In order to be able interconnect the two metal parts 101, 102 by means of a hard soldering process, a mass percentage of magnesium from the mass of the first metal part 101 and from the mass of the second metal part 102 is less than 1% in total. In particular, the mass percentage of magnesium of the first metal part 101 may be less than 0.5% of the mass of the first metal part 101, wherein the mass percentage of magnesium of the second metal part may be less than 0.5% of the mass of the second metal part 102.

To manufacture the fluid-permeable cooler 100, the first metal part 101, the second metal part 102 and the cooling structure 1 can preferably be assembled in the same manufacturing step by means of a soldering process.

1. A fluid-permeable cooler (100) for cooling a power module (200) that comprises a power substrate (208), wherein the fluid-permeable cooler (101) comprises:
a first metal part (101);
a second metal part (102), wherein the first metal part (101) and the second metal part (102) are interconnected by a soldering process and define a cooling channel (111) through which a fluid can flow; and
a cooling structure (1) located in the cooling channel (111), wherein the first metal part (101) comprises a receiving region (109) to which the power module (208) can be attached, and wherein the first metal part (101) is made from a metal material which has an expansion coefficient that is greater than an expansion coefficient of the power substrate (208).

2. The fluid-permeable cooler (100) according to claim 1, wherein the metal material of the first metal part (101) has a yield strength greater than 30 N/mm² after the soldering process.

3. The fluid-permeable cooler (100) according to claim 1, wherein the metal material of the first metal part (101) has a thermal conductivity coefficient greater than 190 W/(m*K).

4. The fluid-permeable cooler (100) according to claim 1, wherein the first metal part (101) and the second metal part (102) are interconnected by a hard soldering process.

5. The fluid-permeable cooler (100) according to claim 1, wherein the metal material of the first metal part (101) comprises magnesium, and the second metal part is made from a metal material which does not comprise magnesium, wherein a mass percentage of magnesium in the first metal part (101) is less than 1%, or
wherein the metal material of the first metal part (101) comprises magnesium, and the second metal part is made from a metal material which comprises magnesium, wherein a mass percentage of magnesium from a mass of the first metal part (101) and from a mass of the second metal part (102) is less than 1% in total.

6. The fluid-permeable cooler (100) according to claim 1, wherein the metal material of the first metal part (101) is an aluminum alloy having a material state O after the soldering process.

7. The fluid-permeable cooler (100) according to claim 1, wherein the metal material of the first metal part (101) is a metal alloy.

8. The fluid-permeable cooler (100) according to claim 1, wherein the metal material of the first metal part (101) is a pure metal.

9. A power electronics assembly (1000) comprising a power module (200) having a power substrate (208) and a fluid-permeable cooler (100) according to claim 1, wherein the power module (200) is attached to the receiving region (109) of the first metal part (101) of the fluid-permeable cooler (100) by the power substrate (208).

10. The power electronics assembly (1000) according to claim 9, wherein the power substrate (100) is made from copper and/or ceramic.

11. The fluid-permeable cooler (100) according to claim 3, wherein the metal material of the first metal part (101) has a thermal conductivity coefficient greater than 200 W/(m*K).
